(19) United States
(12) Patent Application Publication
(10) Pub. No.: US 2026/0013388 A1
(43) Pub. Date: Jan. 8, 2026

(54) PRESSING APPARATUS, METHOD OF MANUFACTURING DISPLAY DEVICE USING THE SAME, AND ELECTRONIC DEVICE

(71) Applicant: Samsung Display Co., Ltd., Yongin-Si (KR)

(72) Inventors: HONGCHUL SHIN, Yongin-si (KR); TETSUYA OKAMOTO, Yongin-si (KR); MINSEOK KANG, Yongin-si (KR)

(21) Appl. No.: 19/077,077

(22) Filed: Mar. 12, 2025

(30) Foreign Application Priority Data
Jul. 4, 2024 (KR) 10-2024-0088430

(51) Int. Cl. H10K 71/50; H01L 21/687

(52) U.S. Cl. CPC H10K 71/50; H01L 21/68785

(57) ABSTRACT

A pressing apparatus includes: an adsorption portion having an adsorption surface, a pad portion located along an edge of the adsorption portion, a body portion under the pad portion, the bod portion supporting the adsorption portion and the pad portion, and a pressing portion covering at least a portion of a side surface of the body portion and attached to the pad portion. The shape of the pad portion is changeable with movement of the pressing portion.

### CROSS-REFERENCE TO RELATED APPLICATION(S)

This application claims priority to and benefits of Korean Patent Application No. 10-2024-0088430 under 35 U.S.C. § 119, filed on Jul. 4, 2024, in the Korean Intellectual Property Office (KIPO), the entire contents of which are incorporated herein by reference.

### BACKGROUND

### 1. Technical Field

Embodiments relate to a pressing apparatus, a method of manufacturing a display device using the pressing apparatus, and an electronic device. More particularly, embodiments relate to a pressing apparatus for lamination process, a method of manufacturing a display device using the pressing apparatus, and an electronic device.

### 2. Description of the Related Art

A display device is a device that displays an image for providing visual information to a user. Among display devices, an organic light emitting diode display device has recently attracted attention.

The display device may include a display panel and a window located on the display panel. Recently, a curved display device that improves user's image immersion and makes the user feel comfortable has been in the market. A window applied to the curved display device may include a flat portion and a curved portion positioned around the flat portion. The curvature makes it challenging to securely attach a window including a flat portion and a curved portion to the display panel.

### SUMMARY

Embodiments provide a pressing apparatus with improved quality.

Embodiments provide a method of manufacturing a display device using the pressing apparatus.

Embodiments provide an electronic device including the display device manufactured by the method of manufacturing the display device.

A pressing apparatus according to an embodiment includes an adsorption portion having an adsorption surface, a pad portion located along an edge of the adsorption portion, a body portion under the pad portion, the body portion supporting the adsorption portion and the pad portion, and a pressing portion covering at least a portion of a side surface of the body portion and attached to the pad portion, wherein a shape of the pad portion is changeable by movement of the pressing portion.

In an embodiment, the pressing portion may be capable of moving outward from a center of the body portion.

In an embodiment, the pad portion changes shape as the pressing portion moves outward from the center of the body portion.

In an embodiment, the adsorption portion may have a first hole extending through the adsorption portion.

In an embodiment, the apparatus may further include a vacuum pad extending through the first hole of the adsorption portion.

In an embodiment, a portion of the vacuum pad may have a hollow cylindrical shape.

In an embodiment, the body portion may have a second hole connected to the first hole, and a portion of the vacuum pad may extend through the second hole.

In an embodiment, the adsorption portion may include a first electrode and a second electrode that are arranged side by side with each other.

In an embodiment, polarity of the first electrode and polarity of the second electrode may be different from each other.

In an embodiment, the adsorption portion may further include a cushion layer located on the first electrode and the second electrode.

In an embodiment, the adsorption portion may include a first portion and a second portion located on the first portion, and at least a portion of a side surface of the second portion may have an inclined surface.

In an embodiment, hardness of the pad portion may be equal to or greater than about 30 shore hardness and equal to or less than about 70 shore hardness.

In an embodiment, the adsorption surface may support an object.

In an embodiment, the adsorption portion may include a first electrode and a second electrode arranged side by side with each other under the adsorption surface.

In an embodiment, the adsorption portion may have a hole extending through the adsorption portion

In an embodiment, the pressing apparatus may further include a penetration portion connected to the hole and including a plurality of the vacuum pads.

A method of manufacturing a display device according to embodiment includes coupling a window to an upper jig, the upper jig having a flat area and a curved area, placing a display panel on a pressing apparatus, placing the window and the display panel in contact with each other, and moving the pressing portion.

In an embodiment, the moving of the pressing portion may include moving the pressing portion outward from a center of the body portion.

In an embodiment, wherein a shape of the pad portion is changed by the moving of the pressing portion outward from the center of the body portion.

In an embodiment, a portion of the window overlapping the curved area may be evenly attached to the display panel by the moving of the pressing portion.

In an embodiment, the adsorption portion may include a first electrode and a second electrode that are arranged side by side with each other.

An electronic device according to an embodiment includes a display device manufactured as described above, a memory configured to store data information, and a processor using the stored data information to transmit image data signal to the display device.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a pressing apparatus according to an embodiment.

FIG. 2 is an exploded perspective view illustrating the pressing apparatus of FIG. 1.

FIG. 3 is a cross-sectional view of the pressing apparatus of FIG. 1 taken along line I-I.

FIG. 4 is a diagram schematically illustrating an example of a stacked structure of an adsorption portion included in the pressing apparatus of FIG. 1.

FIGS. 5 and 6 are cross-sectional views illustrating some of a step of bonding the display panel and the window to each other using the pressing apparatus of FIG. 1.

FIG. 7 is an enlarged cross-sectional view of the area A of FIG. 6.

FIG. 8 is a perspective view illustrating the pressing apparatus of FIG. 1.

FIG. 9 is a cross-sectional view illustrating a part of a step of bonding the display panel and the window to each other using the pressing apparatus of FIG. 1.

FIG. 10 is an enlarged cross-sectional view of area B of FIG. 9.

FIG. 11 is a diagram schematically illustrating another example of a stacked structure of an adsorption portion included in the pressing apparatus of FIG. 1.

FIG. 12 is a block diagram illustrating an electronic device according to embodiments.

FIG. 13 is a schematic diagram of an electronic device according to various embodiments.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

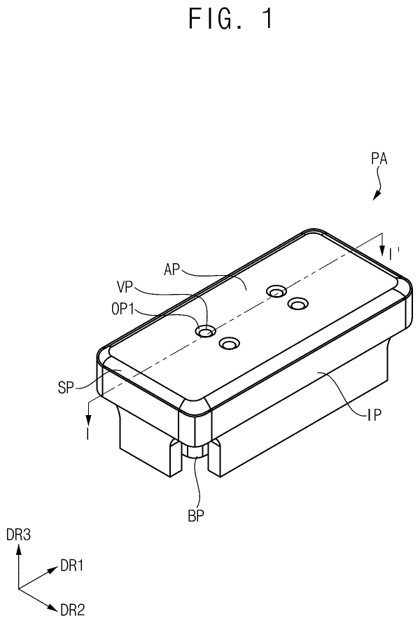

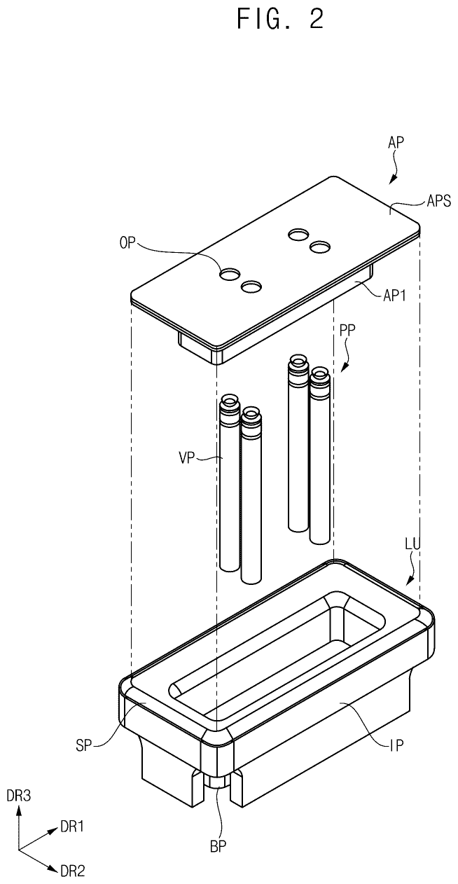

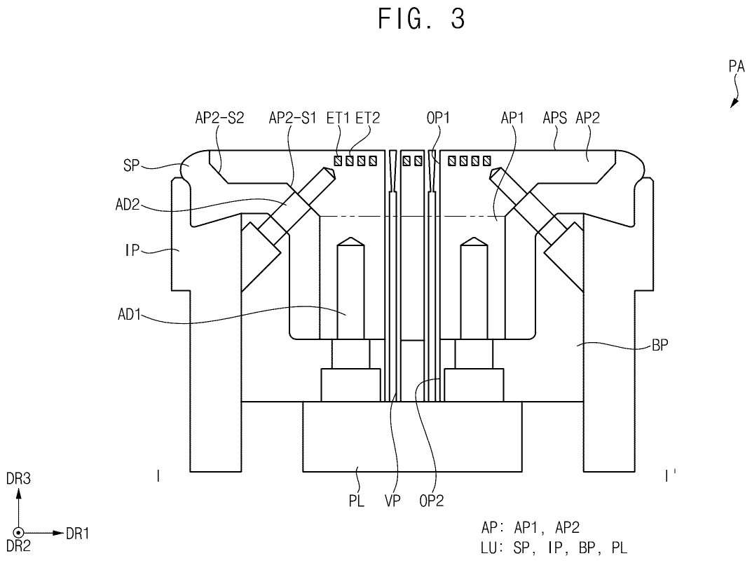

FIG. 1 is a perspective view illustrating a pressing apparatus according to an embodiment. FIG. 2 is an exploded perspective view illustrating the pressing apparatus of FIG. 1. FIG. 3 is a cross-sectional view of the pressing apparatus of FIG. 1 taken along line I-I.

Referring to FIGS. 1, 2, and 3, a pressing apparatus PA according to an embodiment may include an adsorption portion AP, a penetration portion PP, a pressing portion IP, a pad portion SP, a body portion BP, and a base plate PL.

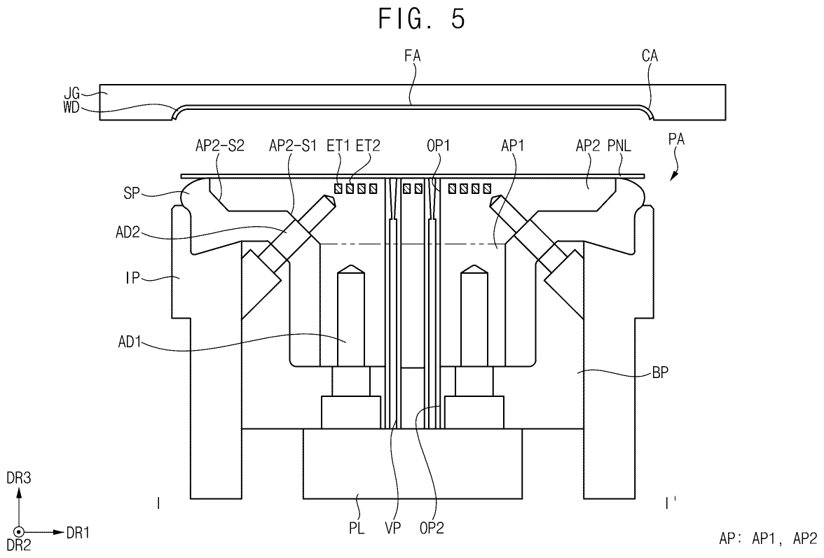

An object such as a display panel (e.g., a display panel PNL of FIG. 5) may be placed on the adsorption portion AP. For example, the adsorption portion AP may include an adsorption surface APS (see FIG. 2), and the object may rest on the adsorption surface APS. In an embodiment, the adsorption surface APS may be a flat surface. For example, the adsorption surface APS may include a plane defined by a first direction DR1 and a second direction DR2 crossing the first direction DR1. However, this disclosure is not limited thereto, and in another embodiment, the adsorption surface APS may be a curved surface. For example, the adsorption surface APS may be a convex surface that curves downward to form a dome shape. For example, the adsorption surface APS may be a curved surface convex in a third direction DR3 orthogonal to the plane formed by the first direction DR1 and the second DR2. For example, the adsorption surface APS may be formed to be highest at the center and incline downward with distance from a center toward an edge.

In an embodiment, a first hole OP1 may be formed in the adsorption portion AP. The first hole OP1 may be a through-hole formed by removing a portion of the adsorption portion AP. For example, the first hole OP1 may be a portion removed from the adsorption surface APS to the lower surface. For example, the first hole OP1 may extend through the adsorption portion AP in the third direction DR3. As illustrated in FIGS. 1 and 2, the number of the first holes OP1 may be four, but this is an example of the number of the first holes OP1, and the number of the first holes OP1 may be variously changed according to embodiments.

In an embodiment, the adsorption portion AP may include a plurality of electrodes. In an embodiment, the adsorption portion AP may include a first electrode ET1 and a second electrode ET2. For example, each of the first electrode ET1 and the second electrode ET2 may be located adjacent to the adsorption surface APS. The first electrode ET1 and the second electrode ET2 may be arranged side by side with each other. For example, the first electrode ET1 and the second electrode ET2 may be arranged alternately and repeatedly. The first electrode ET1 and the second electrode ET2 may have different polarities. For example, the first electrode ET1 may have a (+) polarity, and the second electrode ET2 may have a (−) polarity. Conversely, the first electrode ET1 may have a (−) polarity and the second electrode ET2 may have a (+) polarity. The first electrode ET1 and the second electrode ET2 having different polarities may provide an electrostatic force. Each of the first electrode ET1 and the second electrode ET2 may be spaced apart from the first hole OP1 in a plan view. For example, the first electrode ET1 and the second electrode ET2 may be located at a portion where the first hole OP1 is not located.

In an embodiment, each of the first electrode ET1 and the second electrode ET2 may include metal. For example, each of the first electrode ET1 and the second electrode ET2 may include copper, tin, silver, aluminum, and/or the like. These materials may be used alone or in combination with each other. However, this disclosure is not limited thereto. The first electrode ET1 and the second electrode ET2 may include the same metal or a different metals.

In an embodiment, the adsorption portion AP may include a first portion AP1 and a second portion AP2. The second portion AP2 may be located on the first portion AP1. The first electrode ET1 and the second electrode ET2 may be located in the second portion AP2. In an embodiment, as illustrated in FIG. 3, the first portion AP1 may have a rectangular shape in a cross-sectional view. For example, a side surface of the first portion AP1 may be a surface perpendicular to the adsorption surface APS. However, this disclosure is not limited thereto, and in another embodiment, the side surface of the first portion AP1 may have an inverted tapered inclined surface. The side surface of the first portion AP1 may be a boundary surface between the pad portion SP to be described later and the first portion AP1.

In an embodiment, at least a portion of a side surface of the second portion AP2 may have an inclined surface. For example, at least a portion of the side surface of the second portion AP2 may have an inclined surface. For example, the side surface of the second portion AP2 may include a first surface AP2-S1, a second surface AP2-S2, a third surface connecting the first surface AP2-S1 to the second surface AP2-S2, and a fourth surface connecting the second surface AP2-S2 to the adsorption surface APS in the cross-sectional view, and each of the first surface AP2-S1 and the second surface AP2-S2 may have an inclined surface. However, this disclosure is not limited thereto, and each of the third surface and the fourth surface may also have an inclined surface like the first surface AP2-S1 and the second surface AP2-S2. The side surface of the second portion AP2 may be a boundary surface between the pad portion SP and the second portion AP2. As at least a portion of the side surface of the second portion AP2 has an inclined surface, it may be easy to assemble the adsorption surface AP to a lower unit LU. The lower unit LU may include a pad portion SP, a pressing portion IP, a body portion BP, and a lower plate PL.

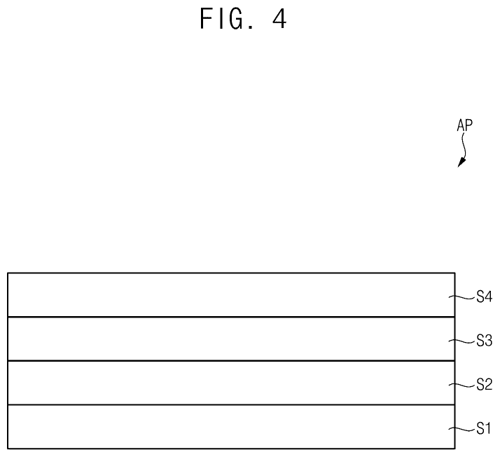

FIG. 4 is a diagram schematically illustrating an example of a stacked structure of an adsorption portion included in the pressing apparatus of FIG. 1.

The adsorption portion AP was described focusing on a shape of the adsorption portion referring to FIGS. 1, 2, and 3, and hereinafter, referring to FIG. 4, the adsorption portion AP will be described focusing on a stacked structure.

Referring to FIG. 4, the adsorption portion AP may include a support portion S1, an insulating layer S2, a metal layer S3, and a cushion layer S4. The insulating layer S2 may be located on the support portion S1, the metal layer S3 may be located on the insulating layer S2, and the cushion layer S4 may be located on the metal layer S3.

The support portion S1 may support the insulating layer S2, the metal layer S3, and the cushion layer S4. The support portion S1 may include a relatively hard material to support the insulating layer S2, the metal layer S3, and the cushion layer S4. For example, the support portion S1 may include nickel, cobalt, aluminum, titanium, stainless steel, invar, and/or the like. These materials may be used alone or in combination with each other. However, this disclosure is not limited thereto, and the support portion S1 may include another kind of material.

The insulating layer S2 may electrically insulate the support portion S1 and the metal layer S3 from each other. In an embodiment, the insulating layer S2 may include ceramic. However, this disclosure is not limited thereto, and the insulating layer S2 may include another type of material. For example, The insulating layer S2 may include polyimide, polyethersulphone, polyacrylate, polyetherimide, polyethylene naphthalate, polyethylene terephthalate, polyphenylene sulfide, polyallylate, polycarbonate, cellulose triacetate, cellulose acetate propionate, poly (arylene ether sulfone), and/or the like, These materials may be used alone or in combination with each other.

The metal layer S3 may be a layer on which the first electrode ET1 and the second electrode ET2 of FIG. 3 are located. For example, the metal layer S3 may include the first electrode ET1 and the second electrode ET2 of FIG. 3.

The cushion layer S4 is a portion that directly contacts the object, and may perform a function of a cushion that absorbs an impact when the object is placed on the adsorption portion AP. For example, the cushion layer S4 may include silicone, urethane, and/or the like. These materials may be used alone or in combination with each other. However, this disclosure is not limited thereto, and the cushion layer S4 may include another type of material.

Referring back to FIGS. 1, 2, and 3, the penetration portion PP may include a vacuum pad VP. The penetration portion PP may fit through the first hole OP1. For example, the vacuum pad VP may fit through a first hole OP1. The vacuum pad VP may be accommodated by a second hole OP2 to be described later. For example, the vacuum pad VP may extend into the first hole OP1 and the second hole OP2 communicating with each other. An inner hole may be formed in the vacuum pad VP. The inner hole of the vacuum pad VP may be connected to an outside of the pressing apparatus PA. For example, the inner hole of the vacuum pad VP may be connected to the outside of the pressing apparatus PA around the adsorption surface APS.

In an embodiment, the vacuum pad VP may be connected to a vacuum pump (not shown). A vacuum suction force generated by the vacuum pump may be transferred to the inner hole of the vacuum pad VP. However, this disclosure is not limited thereto, and the vacuum pad VP may be connected to a solenoid valve and/or the like.

As the pressing apparatus PA according to an embodiment includes the first electrode ET1, the second electrode ET2, and the vacuum pad VP, an electrostatic force and a vacuum suction force may be generated to firmly adsorb and fix the object to the adsorption portion AP. For example, it may be easy for the display panel (for example, the display panel PNL of FIG. 5) to be fixed to the adsorption portion AP by suction force. For example, during a lamination process, the pressing apparatus PA may be located in the chamber. When the chamber is in a vacuum state, the object may be firmly adsorbed and fixed to the adsorption portion AP through the first electrode ET1 and the second electrode ET2. In addition, when the chamber is under atmospheric pressure, the object may be firmly adsorbed and fixed to the adsorption portion AP through the first electrode ET1, the second electrode ET2, and the vacuum pad VP.

In an embodiment, the vacuum pad VP may include a first portion and a second portion. The second portion may be located on the first portion. The first portion may have a hollow cylindrical shape. For example, as illustrated in FIG. 3, the first portion may have a rectangular shape in the cross-sectional view. For example, a portion (i.e., the first portion) of the vacuum pad VP may have a hollow cylindrical shape. The second portion may have a truncated conical shape. For example, the second portion may have a truncated conical shape having a width in the first direction DR1 that decreases as it approaches the first portion. For example, as illustrated in FIG. 3, the second portion may have an inverted trapezoidal shape in the cross-sectional view. However, this disclosure is not limited thereto, and a shape of the vacuum pad VP may be variously changed according to embodiments. For example, the second portion may be omitted. In this case, the vacuum pad VP may have a hollow cylindrical shape extending from one end to the other.

The pad portion SP may be located on a side surface of the adsorption portion AP. For example, the pad portion SP may cover at least a portion of the side surface of the adsorption portion AP. For example, the pad portion SP may cover side surfaces of the first portion AP1 and the second portion AP2 of the adsorption portion AP. For example, the pad portion SP may cover the side surface of the first portion AP1, the first surface AP2-S1, the second surface AP2-S2, the third surface connecting the first surface AP2-S1 to the second surface AP2-S2, and the fourth surface connecting the second surface AP2-S2 and the adsorption surface APS.

In an embodiment, the pad portion SP may include silicone, urethane, and/or the like. These materials may be used alone or in combination with each other. In an embodiment, hardness of the pad portion SP is equal to or greater than about 30 shore hardness and equal to or less than about 70 shore hardness. For example, the hardness of the pad portion SP is about 50 shore hardness. If the hardness of the pad portion SP is less than about 30 shore hardness, during a lamination process of bonding a window (e.g., a window WD of FIG. 5) and the display panel (e.g., the display panel PNL of FIG. 5), the window may not be evenly attached to the display panel. If the hardness of the pad portion SP exceeds about 70 shore hardness, the pad portion SP may not yield enough when the pressing portion IP moves.

In an embodiment, an edge of the pad portion SP may be curved or rounded. For example, the edge of the pad portion SP may be formed to curve downward as a distance from the adsorption surface APS increases. The edge of the pad portion SP may be a portion surrounding the adsorption surface APS in the plan view. For example, the edge of the pad portion SP may be a portion extending from the adsorption surface APS in the plan view.

In an embodiment, the pad portion SP may be attached to the adsorption portion AP. For example, the pad portion SP may be attached to a side surface of the adsorption portion AP. For example, the pad portion SP and the adsorption portion AP may be integrally formed. However, this disclosure is not limited thereto, and in another embodiment, the pad portion SP may be spaced apart from the adsorption portion AP. In this case, there may be a slight gap between the pad portion SP and the adsorption portion AP.

The body portion BP may be located under the pad portion SP and the adsorption portion AP. The body portion BP may support the pad portion SP and the adsorption portion AP. In an embodiment, the body portion BP may define the second hole OP2. The second hole OP2 may communicate with the first hole OP1. The second hole OP2 and the first hole OP1 may be connected to each other to form a penetrating hole extending from the adsorption surface APS to a lower surface of the body portion BP. The vacuum pad VP may be accommodated by the penetration hole.

The pressing portion IP may cover at least a portion of a side surface of the body portion BP. In addition, the pressing portion IP may cover at least a portion of the pad portion SP. For example, the pressing portion IP may cover at least a portion of the pad portion SP located below the edge of the pad portion SP. The pressing portion IP may be attached to the pad portion SP to deform a shape of the pad portion SP. A method in which the pressing portion IP deforms the shape of the pad portion SP will be described in detail later.

The base plate PL may be located under the body portion BP. The base plate PL may support the body portion BP, the pad portion SP, and the adsorption portion AP.

In an embodiment, the body portion BP and the adsorption portion AP may be coupled to each other by a first coupling member AD1. For example, the body portion BP and the first portion AP1 of the adsorption portion AP may be coupled to each other by a first coupling member AD1. In addition, the pressing portion IP, the body portion BP, the pad portion SP, and the adsorption portion AP may be coupled to each other by a second coupling member AD2. For example, the pressing portion IP, the body portion BP, the pad portion SP, and the second portion AP2 of the adsorption portion AP may be coupled to each other by a second coupling member AD2. Each of the first coupling member AD1 and the second coupling member AD2 may include bolts, but this disclosure is not limited thereto. The first coupling member AD1 and the second coupling member AD2 are illustrated in FIG. 3.

Hereinafter, a lamination process performed using the pressing apparatus PA according to an embodiment will be described in detail with reference to FIGS. 5, 6, 7, 8, 9, and 10.

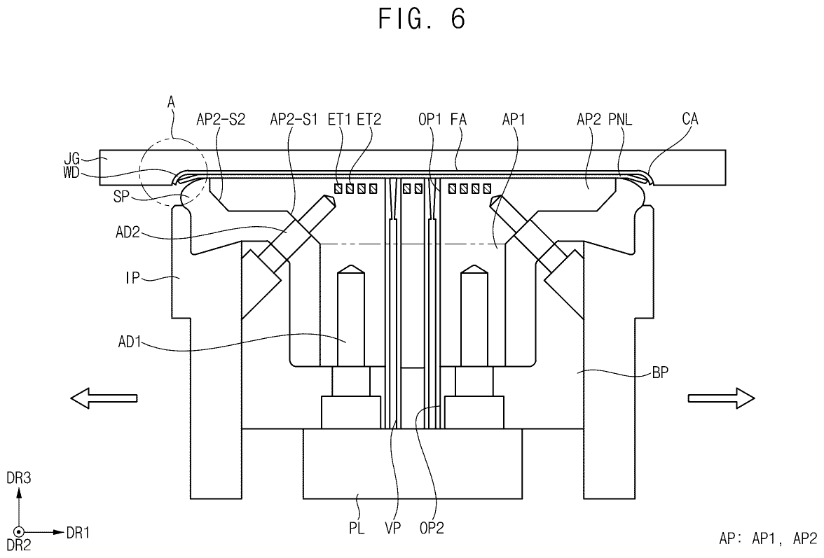

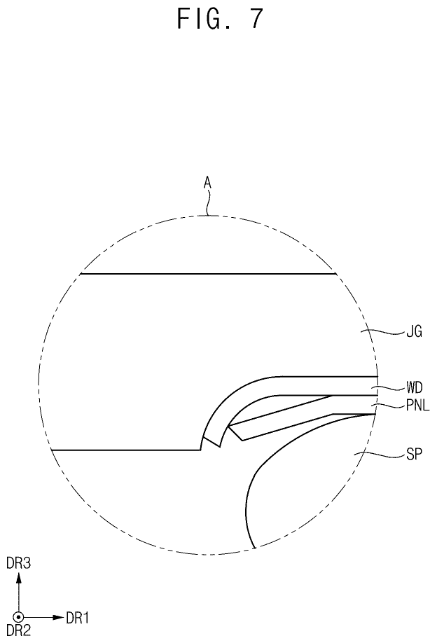

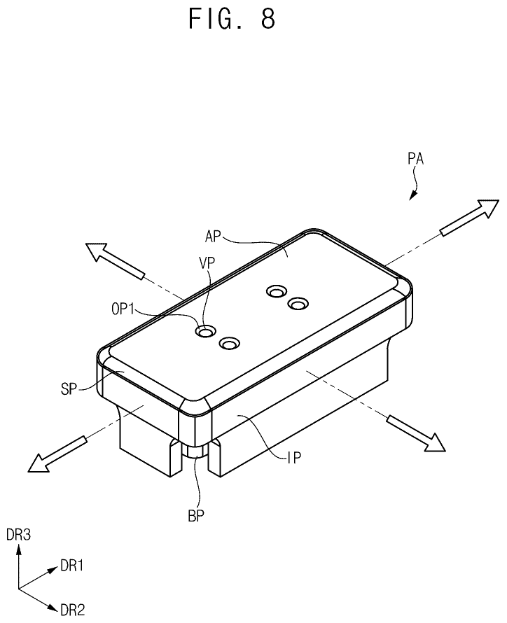

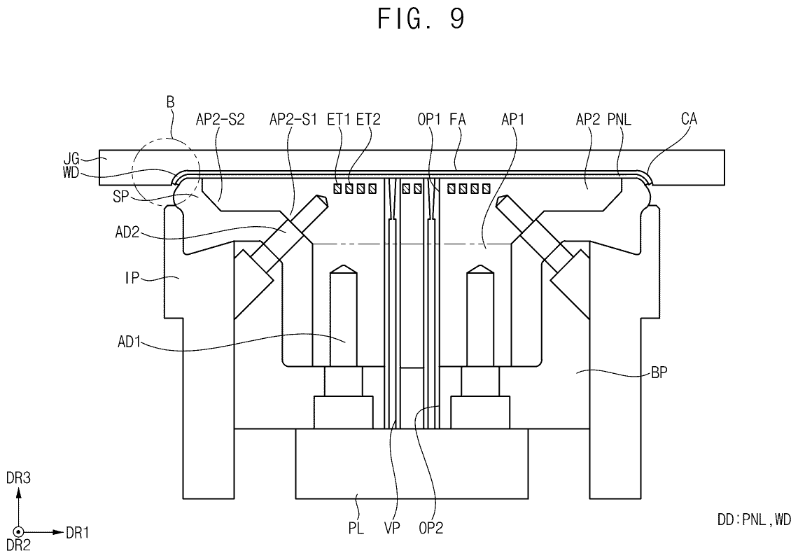

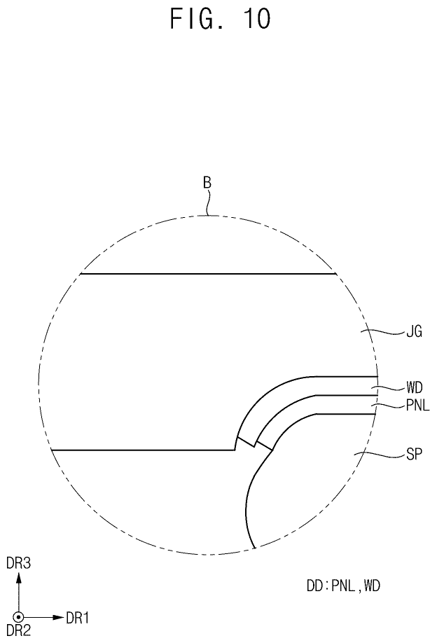

FIGS. 5 and 6 are cross-sectional views illustrating the process of bonding the display panel and the window to each other using the pressing apparatus of FIG. 1. FIG. 7 is an enlarged cross-sectional view of the area A of FIG. 6. FIG. 8 is a perspective view illustrating the pressing apparatus of FIG. 1. FIG. 9 is a cross-sectional view illustrating a part of a step of bonding the display panel and the window to each other using the pressing apparatus of FIG. 1. FIG. 10 is an enlarged cross-sectional view of area B of FIG. 9.

Referring to FIG. 5, the display panel PNL may rest on the pressing apparatus PA. For example, the display panel PNL may rest on the adsorption portion AP. For example, the display panel PNL may rest on the adsorption surface APS. As described above, as the pressing apparatus PA includes the first electrode ET1, the second electrode ET2, and the vacuum pad VP, which keeps the display panel PNL firmly fixed to the adsorption portion AP.

The display panel PNL may emit light. For example, a plurality of pixels may be located on the display panel PNL. Each of the plurality of pixels may emit light. Each of the plurality of pixels may be repeatedly located on the display panel PNL. For example, the plurality of pixels may be repeatedly located along the first direction DR1 and the second direction DR2.

An upper jig JG may be located on the pressing apparatus PA. The upper jig JG may include an upper surface and a lower surface. The lower surface of the upper jig JG may be a surface facing the pressing apparatus PA. The upper surface of the upper jig JG may be a surface opposite to the lower surface of the upper jig JG.

The upper jig JG may include a flat area FA and a curved area CA. For example, the lower surface of the upper jig JG may include a flat area FA and a curved area CA. The flat area FA of the upper jig JG may include a plane. For example, the flat area FA of the upper jig JG may include a plane formed by the first direction DR1 and the second direction DR2. The curved area CA of the upper jig JG may surround the flat area FA. The curved area CA of the upper jig JG may include a curved surface. For example, the curved area CA of the upper jig JG may be formed to incline toward the display panel PNL with increasing distance from a center of the flat area FA.

The window WD may be attached to the upper jig JG. For example, the window WD may be attached to the lower surface of the upper jig JG. For example, the window WD may be attached to the flat area FA and the curved area CA of the upper jig JG. The window WD may include a flat portion and a curved portion. The flat portion of the window WD may have a shape corresponding to the flat area FA of the upper jig JG. For example, the flat portion of the window WD may include a flat surface. For example, the flat portion of the window WD may include a flat surface formed by a first direction DR1 and a second direction DR2. The flat portion of the window WD may overlap the flat area FA of the upper jig JG in the plan view. The curved portion of the window WD may have a shape corresponding to the curved area CA of the upper jig JG. For example, the curved portion of the window WD may include a curved surface. For example, the curved portion of the window WD may curve toward the display panel PNL as distance from a center of the flat portion of the window increases. The curved portion of the window WD may overlap the curved area CA of the upper jig JG.

Referring to FIGS. 6 and 7, at least a portion of the window WD and at least a portion of the display panel PNL may be bonded to each other. For example, at least the portion of the window WD and at least the portion of the display panel PNL may be bonded to each other by optical clear adhesive (“OCA”), optical clear resin (“OCR”), or pressure sensitive adhesive (“PSA”). However, this disclosure is not limited thereto. In an embodiment, the upper jig JG to which the window WD is attached may move toward the display panel PNL so that at least a portion of the window WD and at least a portion of the display panel PNL may come in contact with each other. However, this disclosure is not limited thereto, and in another embodiment, the pressing apparatus (e.g., the pressing apparatus PA of FIG. 5) on which the display panel PNL rests may move toward the window WD that at least a portion of the window WD and at least a portion of the display panel PNL may contact each other. For convenience, hereinafter, the description will focus on the case where the upper jig JG moves toward the display panel PNL.

As the upper jig JG to which the window WD is attached moves toward the display panel PNL, most of the flat portion of the window WD may be attached to the display panel PNL. For example, as the upper jig JG with the window WD moves, most of the flat portion of the window WD may be evenly and well attached to the display panel PNL. In an embodiment, as the upper jig JG moves to put the flat portion of the window WD in contact with the display panel PNL so that the two parts will be attached. However, as illustrated in FIG. 7, the curved portion of the window WD and the flat portion adjacent to the curved portion of the window WD may not be attached to the display panel PNL just by an operation of moving the upper jig JG with the window WD to contact the display panel PNL.

As the upper jig JG to which the window WD is attached moves toward the display panel PNL, the flat portion of the window WD may be uniformly attached to the display panel PNL. However, the curved portion of the window WD may not be well attached to the display panel PNL. As depicted in FIG. 7, less than all of the curved portion of the window WD may be in contact with the display panel PNL.

Referring further to FIGS. 8, 9, and 10, the pressing portion IP attached to the pad portion SP may move. For example, the pressing portion IP may move outward from the center of the pressing apparatus (for example, the pressing apparatus PA of FIG. 5), as shown by the arrows in FIG. 6 and FIG. 8. For example, the pressing portion IP may move outward from the center of the body portion BP. For example, the pressing portion IP may move outward from the pressing apparatus on a plane formed by the first direction DR1 and the second DR2, such as the plane of the adsorption surface APS. For example, as illustrated by the arrows in FIGS. 6 and 8, the pressing portion IP may move in a direction in which the pressing portion IP contacts the pad portion SP. For example, a portion of the pressing portion IP which contacts the pad portion SP in the first direction DR1 may move in the first direction DR1, and a portion of the pressing portion IP which contacts the pad portion SP in the second direction DR2 may move in the second direction DR2. The pressing portion IP may move outward from the center of the body portion BP by moving away from an edge of the body portion BP. For example, when the pressing portion IP moves outward from the center of the body portion BP, the pressing portion IP and the body portion BP may be spaced apart from each other in the plan view, and the body portion BP and the pressing portion IP may be connected to each other by a connecting member, and/or the like. However, this disclosure is not limited thereto, mechanism by which the pressing portion IP moves outward from the center of the body portion BP may be variously changed.

As the pressing portion IP moves, a shape of the pad portion SP attached to the pressing portion IP may be changed and the pad portion SP may press against the display panel PNL. This change in shape is depicted in portion A of FIG. 6 compared with portion B of FIG. 9. For example, at least a portion of the pad portion SP may be stretched along a moving direction of the pressing portion IP. That is, as the pressing portion IP moves, a volume of the pad portion SP may be changed.

As the pad portion SP is stretched along the moving direction of the pressing portion IP, pressure may be applied to the display panel PNL and the window WD. For example, as the shape of the pad portion SP is changed and the pad portion SP presses against the display panel PNL, the portion of the display panel PNL that overlaps the curved portion of the window WD presses against the curved portion of the window WD. The flat portion of the window WD that is adjacent to the curved portion of the window WD may be pressed against the portion of the display panel PNL overlapping the flat portion adjacent to the curved portion of the window WD. With the outward movement of the pressing portion IP, a pressing force may be applied to a portion where the display panel PNL and the window WD are not in contact or not bonded to each other. Accordingly, the curved portion of the window WD and the flat portion adjacent to the curved portion may be evenly and securely attached to the display panel PNL. For example, as the shape of the pad portion is changed, the window WD including the curved portion and the flat portion may be “ironed out” to evenly attach to the display panel PNL. This may result in the display panel PNL having a shape that substantially matches the shape of the window WD.

This disclosure is not limited to the specifics described, and when the pad portion SP has a shape that substantially matches the curved area CA of the upper jig JG, a process of moving the pressing portion IP outward may be omitted. For example, when an edge of the pad portion SP has a shape that substantially matches the curved area CA of the upper jig JG, a process of moving the pressing portion IP may be omitted. This may be because when the edge of the pad portion SP has a shape substantially corresponding to the curved area CA of the upper jig JG, the window WD may be evenly attached to the display panel PNL by placing the window WD in contact with the display panel PNL.

According to an embodiment, a process of transforming a shape of the display panel PNL may not be necessary in the process of bonding the window WD including the curved portion and the flat portion with the display panel PNL. Accordingly, a separate guide film and/or a clamp for changing the shape of the display panel PNL resting on the adsorption portion AP may not be required. For example, even without a process of changing the shape of the display panel PNL, as the pressing portion IP moves, the window WD may be uniformly attached to the display panel PNL.

The display device DD may be manufactured through the lamination process described with reference to FIGS. 5, 6, 7, 8, 9, and 10. The display device DD may be understood as a configuration including the display panel PNL and the window WD. However, the present disclosure is not limited thereto, and the display device DD may further include a polarizing film, a panel lower member, a heat dissipating member, and/or the like.

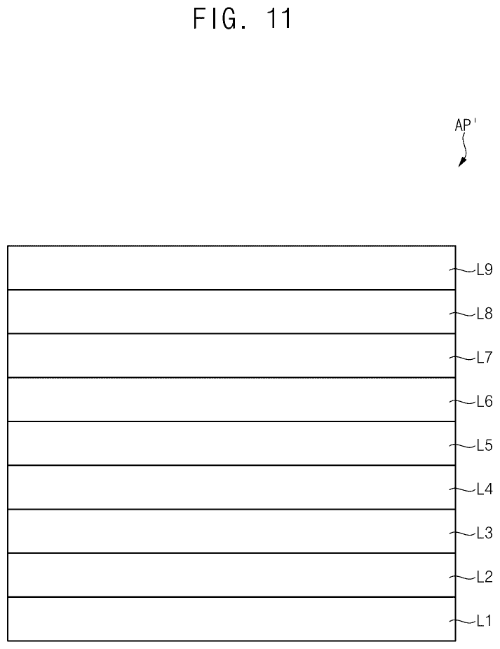

FIG. 11 is a diagram schematically illustrating another example of a stacked structure of an adsorption surface included in the pressing apparatus of FIG. 1.

Referring to FIG. 11, an adsorption portion AP′ according to another embodiment may include a support portion L1, a first adhesive layer L2, a cushion layer L3, a second adhesive layer L4, a first insulating layer L5, a third adhesive layer L6, a metal layer L7, a fourth adhesive layer L8, and a second insulating layer L9.

The support portion L1 may include a relatively hard material to support the cushion layer L3, the first insulating layer L5, the metal layer L7, and the second insulating layer L9. For example, the support portion L1 may include nickel, cobalt, aluminum, titanium, stainless steel, invar, and/or the like. These materials may be used alone or in combination with each other. However, this disclosure is not limited thereto, and the support portion L1 may include another kind of material.

The cushion layer L3 may be located on the support portion L1. The cushion layer L3 may absorb any impact when an object such as the display panel (e.g., the display panel PNL of FIG. 5) is placed on the adsorption portion AP′. For example, the cushion layer L3 may include polyethylene, among other possibilities.

In an embodiment, the support portion L1 and the cushion layer L3 may be attached to each other by the first adhesive layer L2. For example, the first adhesive layer L2 may include a polymer material, but this disclosure is not limited thereto.

The first insulating layer L5 may be located on the cushion layer L3. The first insulating layer L5 may electrically insulate the metal layer L7 and the cushion layer L3. The first insulating layer IL5 may include polyimide, polyethersulphone, polyacrylate, polyetherimide, polyethylene naphthalate, polyethylene terephthalate, polyphenylene sulfide, polyallylate, polycarbonate, cellulose triacetate, cellulose acetate propionate, poly (arylene ether sulfone), and/or the like. These materials may be used alone or in combination with each other.

In an embodiment, the cushion layer L3 and the first insulating layer L5 may be attached to each other by the second adhesive layer L4. For example, the second adhesive layer L4 may include a polymer material, but this disclosure is not limited to the material explicitly mentioned herein.

The metal layer L7 may be located on the first insulating layer L5. The metal layer L7 may be a layer on which the first electrode ET1 and the second electrode ET2 of FIG. 3 are located. For example, the metal layer L7 may include the first electrode ET1 and the second electrode ET2 of FIG. 3.

In an embodiment, the first insulating layer L5 and the metal layer L7 may be attached to each other by the third adhesive layer L6. For example, the third adhesive layer L6 may include a polymer material, but this disclosure is not limited to compositions explicitly mentioned herein.

The second insulating layer L9 may be located on the metal layer L7. For example, the second insulating layer L9 may include polyimide, polyethersulphone, polyacrylate, polyetherimide, polyethylene naphthalate, polyethylene terephthalate, polyphenylene sulfide, polyallylate, polycarbonate, cellulose triacetate, cellulose acetate propionate, poly (arylene ether sulfone), and/or the like, These materials may be used alone or in combination with each other.

In an embodiment, the metal layer L7 and the second insulating layer L9 may be attached to each other by the fourth adhesive layer L8. For example, the fourth adhesive layer L8 may include a polymer material, among other possibilities.

The display device (e.g., the display device DD of FIG. 9) according to embodiments may be applied to various electronic devices. An electronic device according to embodiments may include the above-described display device, and may further include a module or device having other additional functions in addition to the display device.

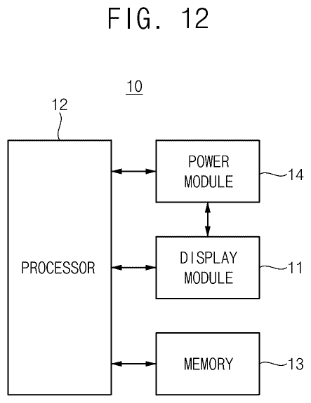

FIG. 12 is a block diagram illustrating an electronic device according to embodiments.

Referring to FIG. 12, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information useful for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of the components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

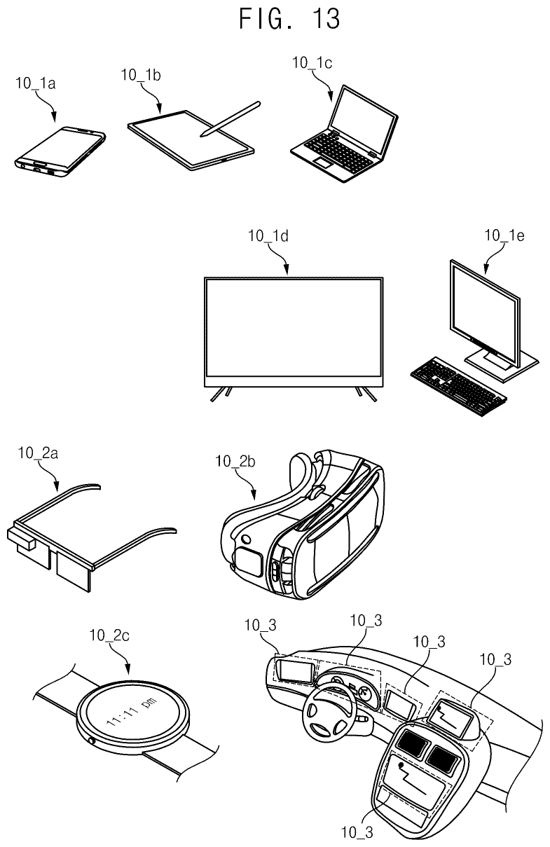

FIG. 13 is a schematic diagram of an electronic device according to various embodiments.

Referring to FIG. 13, various electronic devices to which display devices according to embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) disposed on a dashboard, a room mirror display, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A pressing apparatus comprising:
an adsorption portion having an adsorption surface;
a pad portion located along an edge of the adsorption portion;
a body portion under the pad portion, the body portion supporting the adsorption portion and the pad portion; and
a pressing portion covering at least a portion of a side surface of the body portion and attached to the pad portion, wherein a shape of the pad portion is changeable by movement of the pressing portion.

2. The pressing apparatus of claim 1, wherein the pressing portion is configured to move outward from a center of the body portion.

3. The pressing apparatus of claim 2, wherein the pad portion changes shape as the pressing portion moves outward from the center of the body portion.

4. The pressing apparatus of claim 1, wherein the adsorption portion has a first hole extending through the adsorption portion.

5. The pressing apparatus of claim 4, further comprising:
a vacuum pad extending through the first hole of the adsorption portion.

6. The pressing apparatus of claim 5, wherein a portion of the vacuum pad has a hollow cylindrical shape.

7. The pressing apparatus of claim 5, wherein the body portion has a second hole connected to the first hole, and
a portion of the vacuum pad extends through the second hole.

8. The pressing apparatus of claim 1, wherein the adsorption portion includes a first electrode and a second electrode that are arranged side by side with each other.

9. The pressing apparatus of claim 8, wherein polarity of the first electrode and polarity of the second electrode are different from each other.

10. The pressing apparatus of claim 8, wherein the adsorption portion further includes a cushion layer located on the first electrode and the second electrode.

11. The pressing apparatus of claim 1, wherein the adsorption portion includes a first portion and a second portion located on the first portion, and
at least a portion of a side surface of the second portion has an inclined surface.

12. The pressing apparatus of claim 1, wherein hardness of the pad portion is equal to or greater than about 30 shore hardness and equal to or less than about 70 shore hardness.

13. The pressing apparatus of claim 1, wherein the adsorption surface supports an object,
the adsorption portion includes a first electrode and a second electrode arranged side by side with each other under the adsorption surface, and
the adsorption portion has a hole extending through the adsorption portion.

14. The pressing apparatus of claim 13, further comprising:
a penetration portion connected to the hole and including a plurality of vacuum pads.

15. A method of manufacturing a display device, the method comprising:
coupling a window to an upper jig, the upper jig having a flat area and a curved area;
placing a display panel on a pressing apparatus, wherein the pressing apparatus includes:
an adsorption portion having an adsorption surface;
a pad portion located along an edge of the adsorption portion;
a body portion under the pad portion, the body portion supporting the adsorption portion and the pad portion; and
a pressing portion covering at least a portion of a side surface of the body portion and attached to the pad portion;
placing the window and the display panel in contact with each other; and
moving the pressing portion.

16. The method of claim 15, wherein the moving of the pressing portion includes moving the pressing portion outward from a center of the body portion.

17. The method of claim 15, wherein a shape of the pad portion is changed by the moving of the pressing portion.

18. The method of claim 15, wherein a portion of the window overlapping the curved area is evenly attached to the display panel by the moving of the pressing portion.

19. The method of claim 15, wherein the adsorption portion includes a first electrode and a second electrode that are arranged side by side with each other.

20. An electronic device comprising:
a display device manufactured according to the method of claim 16;
a memory configured to store data information; and
a processor using the stored data information to transmit image data signal to the display device.
